(19) United States
(12) Patent Application Publication
(10) Pub. No.: US 2004/0146005 A1
(43) Pub. Date: Jul. 29, 2004

(54) Protection switching apparatus and method using node group in ring ATM system

(76) Inventor: Houn-Joung Rim, Seongnam-city (KR)

Correspondence Address: Robert E. Bushnell, Suite 300, 1522 K Street, N.W., Washington, DC, 20005, US

(21) Appl. No.: 10/732,353

(22) Filed: Dec. 11, 2003

(30) Foreign Application Priority Data
Jan. 29, 2003 (KR) 2003-6020

(51) Int. Cl. G01R 31/08

(52) U.S. Cl. 370/217

(57) ABSTRACT

A protection switching apparatus and method uses a node group in a ring ATM system, wherein all connections existing in a node is regarded as one group and a ring node ID is given to each node, thereby including all node IDs of nodes with a subscriber in a GFC (Generic Flow Control) field of an ATM (Asynchronous Transfer Mode) cell that passes through every traffic of the ring, and switching every traffic in a node, the moment protection switching for an arbitrary node group is required.

### CLAIM OF PRIORITY

This application makes reference to, incorporates the same herein, and claims all benefits accruing under 35 U.S.C. § 119 from an application for PROTECTION SWITCHING APPARATUS AND METHOD USING NODE GROUP IN RING ATM SYSTEM earlier filed in the Korean Intellectual Property Office on 29 Jan. 2003 and thereby duly assigned Serial No. 2003-6020.

### BACKGROUND OF THE INVENTION

1. Field of the Invention

The present invention relates to a protection switching apparatus and method using a node group in the ring ATM (Asynchronous Transfer Mode) system, wherein all connections existing in a node is regarded as one group and a ring node ID (identification) is given to each node, thereby switching every traffic in a node when protection switching for an arbitrary node group is required.

2. Description of the Related Art

To operate the network more stably, provide users with good quality services without interruption, and maximize efficiency of the network, it is very important to prepare appropriate countermeasures against network failure or deterioration of performance.

Among the countermeasures, there is a survivability enhancing structure. The survivability enhancing structure can be divided into two kinds: protection switching and restoration. Protection switching involves pre-setting path and bandwidth between nodes to be able to restore network service immediately in the event of failure. Restoration involves, as the name implies, restoring any interrupted service back to a normal state by using every possible path and capacity of the network after failure.

There are two types of protection switching methods. One is individual protection switching method for performing protection switching on every VP (Virtual Path) NC (Virtual Channel) connection, and the other is group protection switching method for performing protection switching collectively by treating a logical bundle of VP/VC connections as one VPI (Virtual Path Identifier)/VCI (Virtual Channel Identifier).

Basically the individual protection switching method is used when there is no protection switching for server layers. Because this method takes too much time to protect/switch every VP/VC connection, it is usually used for protecting part of VP/VC connection where high reliability is required.

In case that protection switching does not exist nor can it be developed, the group protection switching method is used for protecting/switching ATM layers within a short time. This quick protection switching is possible because the logical bundle of VP/VC connections is treated like one VPI/VCI. The logical bundle with more than one ATM VP sharing the identical transmission path is called a VP group. Work VP group and protection VP group always exist as a pair. The moment protection switching takes place, all VPs in a VP group are switched at the same time.

This type of group protection switching, however, has not only its standard, but also the systems are very difficult and complicated to apply, and when performing switching operation according to the switching schedule (time) in response to an ATM alarm cell.

### SUMMARY OF THE INVENTION

It is, therefore, an object of the present invention to provide a protection switching apparatus and method using a node group in a ring ATM system, wherein all connections existing in a node is regarded as one group, and a ring node Identification (ID) is given to each node, and node ID information of the node with a subscriber in all traffics passing through the ring is included in a GFC (Generic Flow Control) field of an ATM (Asynchronous Transfer Mode) cell, thereby switching every traffic in a node when protection switching for an arbitrary node group is required.

It is another object to provide a technique and apparatus where the protection switching process can be completed much faster by using the GFC field for the ring ATM system.

It is yet another object to provide a protection switching apparatus and method using a node group in a ring ATM system that is easy to implement and is cost effective.

It is still another object to provide a protection switching apparatus and method that is more efficient.

To achieve the above and other objects, there is provided a protection switching apparatus using a node group in a ring ATM system, the apparatus includes: a physical layer processor for extracting an ATM cell from a receive frame from a physical layer and loading a cell that is received from an ATM layer to the frame; a pair of traffic filters for generating an alarm cell if fault is sensed in the opposite port, for transmitting the alarm cell, each of the traffic filters including a cell drop register for storing ring node identification, whereby if a cell with a designated ring node identification from a unidirectional network interface is received in a first field that is stored in a cell drop register, the traffic filter drops the cell; and if a cell with a designated ring node identification is inputted in a first field that is not stored in the cell drop register, the traffic filter passes the cell, for detecting an alarm cell that is received from another ring node, for setting an allocated bit value in a second field to a second value, and for transmitting the cell; a controller for storing a ring node identification of its own in the cell drop register of the traffic filter that transmitted the alarm cell recognition signal when receiving an alarm cell recognition signal from the traffic filter, for deleting the ring node identification, and for transmitting a control signal to set its allocated bit in the alarm cell to the traffic filter; and a cell routing unit for routing the cell to a local bus when receiving a cell with its designated ring node identification to the first field of the input cell, and for routing the cell to a through bus when receiving a cell without its designated ring node identification to the first field of the receive cell.

Another aspect of the present invention provides a protection switching method using a node group in a ring ATM system, the method includes: a first step in which a network ATM ring unit of a ring node recognizes port fault and notifies to an opposite network ATM ring unit about the port fault; a second step in which a controller designates a ring node identification of the controller to a cell drop register of the network ATM ring unit with the port fault, and deletes the ring node identification out of a cell drop register of the opposite network ATM ring unit; a third step in which the network ATM ring unit that is notified of the port fault generates an alarm cell and transmits the alarm cell; a fourth step in which the controller, upon receiving an alarm cell from another ring node, designates a ring node identification of the controller to the cell drop register of an alarm cell-receiving network ATM ring unit, and deletes the ring node identification out of the cell drop register of the opposite network ATM ring unit; and a fifth step in which the alarm cell-receiving network ATM ring unit adds node information of the unit to the write alarm cell, and transmits the alarm cell including the node information of the unit.

Still another aspect of the present invention presents a protection switching method using a node group in a ring ATM system, the method includes the steps of: if a network-connection node receives an alarm cell, detecting, at a network ATM ring unit, that the alarm cell has been received, and extracting node information from the alarm cell; notifying, at the network ATM ring unit that detected receive of the alarm cell, to a controller about the receive of the alarm cell, and transmitting the node information extracted from the alarm cell to the controller; deleting, at the controller, ring node identifications of nodes based on the node information included in the alarm cell of a cell drop register of the network ATM ring unit in which the alarm cell is received; and storing, at the controller, ring node identifications of nodes based on the node information include in the alarm cell of an cell drop register of an opposite network ATM ring unit of the network ATM ring unit to which the alarm cell is inputted.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a diagram illustrating connection between DSLAM (Digital Subscriber Line Access Multiplexer) and ATM switch;

FIG. 2 is a diagram illustrating the configuration of a ring ATM system, in which all subscribers within the ring are concentrated to node A, and to the Internet through an ATM switch and NAS (Network Access Server);

FIG. 3 is a diagram illustrating the configuration of a ring ATM system to which the present invention is applied;

FIG. 4 is a structural diagram of an alarm cell for use in the ring ATM system of FIG. 3;

FIG. 5 shows the internal structure of a protection switching apparatus using a node group in the ring ATM system according to one embodiment of the present invention;

FIG. 6 is a conceptual diagram of the internal structure of a traffic filter illustrated in FIG. 5;

FIG. 7 is a flow chart describing a protection switching method in a ring node failure according to one embodiment of the present invention;

FIG. 8 is a flow chart describing a protecting switching method in a ring node to which an alarm cell is transmitted according to one embodiment of the present invention;

FIG. 9 is a flow chart describing a protection switching method in a network-connection node to which an alarm cell is transmitted according to one embodiment of the present invention; and

FIG. 10 shows an example of a computer including a computer-readable medium having computer-executable instructions for performing a method of the present invention.

### DETAILED DESCRIPTION OF THE PREFERRED EMBODIMENTS

The following detailed description will present a protection switching apparatus using a node group in a ring ATM system according to a preferred embodiment of the present invention.

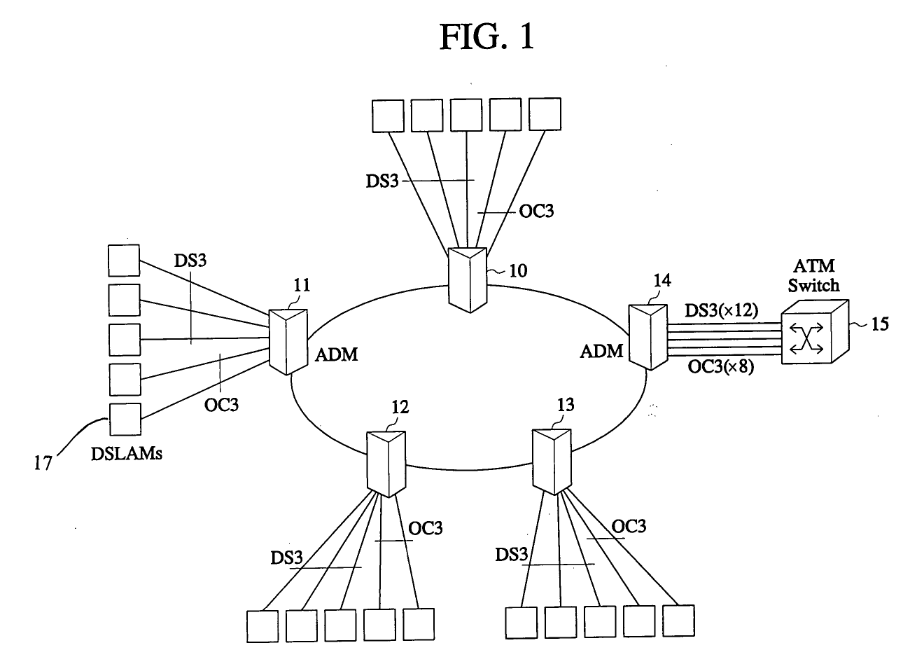

FIG. 1 is a diagram illustrating connection between a DSLAM (Digital Subscriber Line Access multiplexer) and an ATM switch. As shown in the drawing, there are five DSLAMs 17 in each of the four local sites 10-13, three of them being connected to a hub site SONET (Synchronous Optical Network) ADM 14 through DS3 links (45 Mbps (megabits per second)) and the other two through OC3 links (155 Mbps).

The hub site 14 has an ATM switch 15 and is connected to Internet through NAS (Network Access Server).

Between twenty DSLAMs 17 located in four local sites 10-13 and the ATM switch 15 of the hub site 14 are twenty SONET circuits using twelve DS3s or eight OC3s. Each circuit is used for transmitting traffic between one DSLAM and one port of the ATM switch 15. Therefore, each DSLAM cannot statistically share the SONET ring capacity.

The ADM 14 adds or drops the SONET circuits for synchronous multiplexing.

ATM ring is implemented using equipment called ATM-ADM. The ATM-ADM, unlike the ADM adds/drops a signal in units of SONET circuit, adds/drops a cell in units of ATM virtual circuit. That is, if the SONET frame is not channelized, the ATM-ADM decides whether to add or drop a cell by checking VPI/VCI value of an ATM cell. Although ADM was able to use only allocated frame slots, the ATM-ADM does not have a fixed number of allocated slots yet it can transmit a cell as it is. In other words, all of the transmitted cells from each DSLAM are statistically multiplexed on the SONET ring. As a result of statistical multiplex, more subscribers are allowed because more bandwidth is gained.

Survivability of the ATM network can be characterized by time for detecting failure or defect, protection switching or restoration completion time, or restoral rate. Network protection switching completion time means the time taken for restoring a damaged entity to a protection entity under a given protection capability once a decision is made to protect the network.

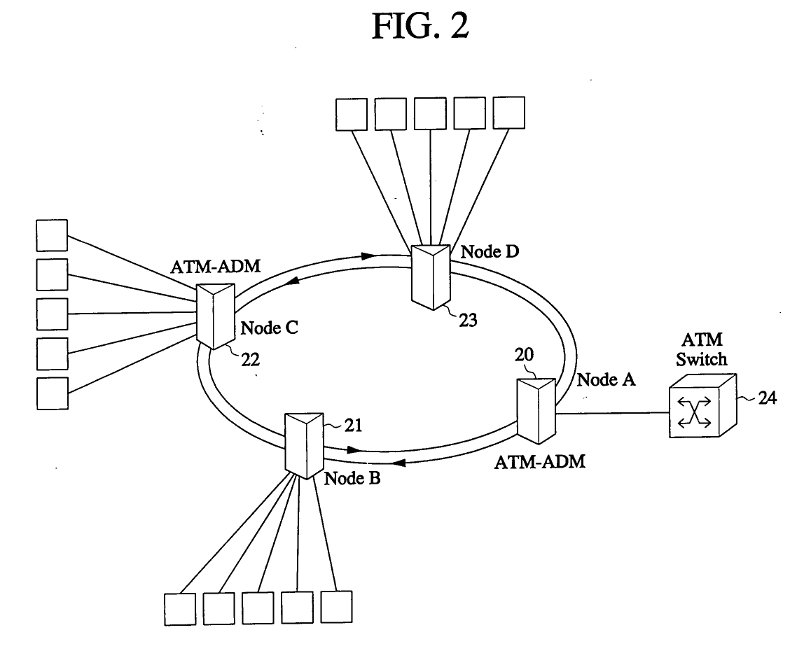

FIG. 2 is a diagram illustrating the configuration of a ring ATM system, in which all subscribers within the ring are concentrated to node A 20, and to the Internet through an ATM switch 24 and NAS. If there is any fault in the path from node B 21 to node A 20, node A 20 performs protection switching, encouraging the subscribers to select the counterclockwise traffic path.

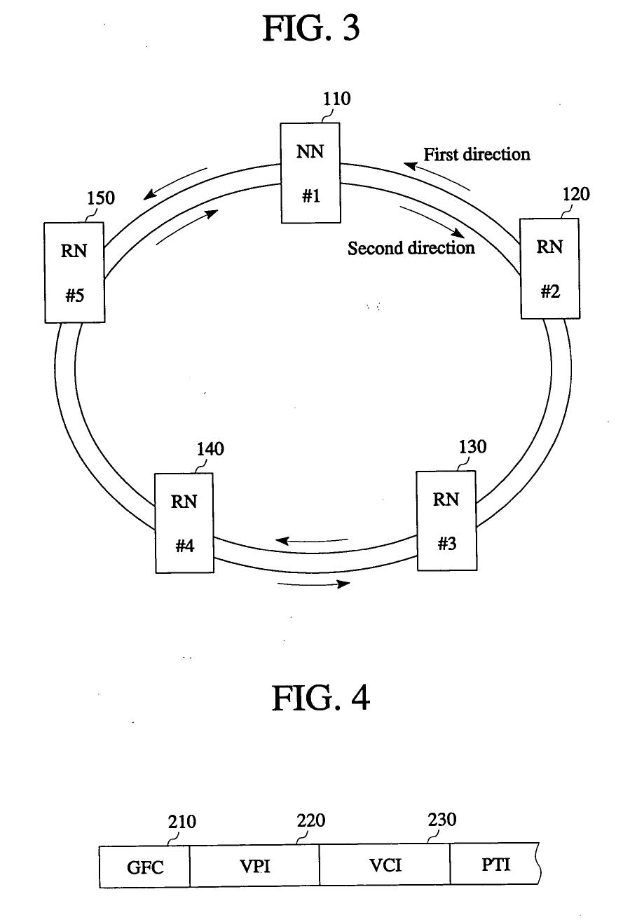

FIG. 3 is a diagram illustrating the configuration of a ring ATM system to which the present invention is applied.

As shown in FIG. 3, the ring ATM system includes a network-connection node 110 and many ring nodes 120-150, performing communication in the ATM mode. The ring ATM system, depending on the number limitary of nodes, can include as many as 16 ring nodes.

When transmitting an ATM cell, the network-connection node 110 and many ring nodes 120-150 transmit the ATM cell to the first and second directions at the same time. When receiving an ATM cell, on the other hand, the network-connection node 110 and many nodes 120-150 select one of the ATM cells that are transmitted to the first and second directions.

Each network-connection node 110 and many ring nodes 120-150 has its own RNID (Ring Node Identification), which is inserted into a GFC (Generic Flow Control) field and transmitted together when an ATM cell is transmitted.

When one of paths within the ring is interrupted, the ring node 120-150 generates an alarm cell for a notify interrupter and later transmits the alarm cell to the network-connection node 110 and the other ring nodes 120-150.

The alarm cell, as shown in FIG. 4, includes a GFC field 210, a VPI field 220, and a VCI field 230.

To the GFC field 210 allocated is a predetermined value. For example, referring to FIG. 3, the network-connection node 110 and the ring nodes 120-150 use 1-5 as their RNID, so values other than 1-5 should be used, e.g. 1xF.

In addition, designating a specific value, e.g. 0xFF, to the VPI field 220, it is possible to distinguish the alarm cell.

Each bit of the VCI field 230 is designed to correspond to each of the ringnodes 120-150, so there is a value for respective ring nodes 120-150. At this time, the least significant bit can be disregarded.

For instance, suppose that the path between ring node 3 (130) and ring node 4 (140) is interrupted. Then, the ring node 3 (130) transmits 1xF to the GFC field 210, and 0xFF to the VPI field 220, and the second bit, which is 1, of the VCI field 230 to ring node 2 (120) (the least significant bit was used to construct the alarm cell).

In like manner, suppose that the path between the ring node 3 (130) and the ring node 4 (140) is interrupted. Then, the ring node 4 (140) transmits 1xF to the GFC field 210, and 0xFF to the VPI field 220, and the third bit, which is 1, of the VCI field 230 to ring node 5 (150) (the least significant bit was used to construct the alarm cell).

The ring node 120-150 that generated the alarm cell cuts off a port for the ATM cells inputting from the fault (interrupted) path to drop the ATM cells including its own RNID. As for ATM cells inputting from the opposite path, the ring node generates a port to enable the GFC field to receive the ATM cells including its own RNID.

Meanwhile, the ring node 120-150 that received the alarm cell extracts the GFC field and VPI field values, recognizes receiving the alarm cell, and decides that the alarm cell-transmitted path has been interrupted. Therefore, the alarm cell-receiving ring node 120-150 cuts off the port for the ATM cells inputting from the fault path and drop the ATM cells including its own RNID. As for ATM cells inputting from the opposite path, the ring node 120-150 interlinks a port to enable the GFC field to receive the ATM cells including its own RNID.

Moreover, the alarm cell-receiving ring node 120-150 writes its node information to the input alarm cell (this addition of node information can be achieved by making its allocated bit value of the VCI field to 1), and periodically transmits this alarm cell including its node information.

For example, if the path between the ring node 3 (130) and the ring node 4 (140) is interrupted, the alarm cell of the ring node 3 (130) generated is transmitted to the ring node 2 (120), and the ring node 2 (120) extracts the GFC field and VPI field values, recognizes receiving the alarm cell, and decides that the path between the ring node 3 (130) and the network-connection node 110 has been interrupted.

In addition, the ring node 2 (120) cuts off the port for the ATM cells inputting from the fault path not to receive any ATM cell from the ring node 3 (130), and drop the ATM cell including its own RNID to the GFC field. As for ATM cells receiving from the opposite path, the ring node 2 (120) interlinks a port to enable the GFC field to receive the ATM cells including its own RNID.

Further, the ring node 2 (120) adds its node information to the alarm cell by making its allocated bit value of the VCI field to 1, and periodically transmits this alarm cell including its node information.

On the other hand, upon receiving the alarm cell, the network-connection node 110 extracts the GFC field and VPI field values, recognizes receiving the alarm cell, and decides that the alarm cell-transmitted path has been interrupted.

Also, the network-connection node 110 finds the fault path by searching which bit in the VCI field has the value 1.

Then the network-connection node 110 interlinks a port for ATM cell inputting from a ring node 120-150 next to the fault path to receive the ATM cells, and cuts off the port for ATM cells inputting from the opposite path.

For instance, if the path between the ring node 3 (130) and the ring node 4 (140) is interrupted, the network-connection node 110, receive the alarm cell from the ring node 3 (130), after it extracts the GFC field and VPI field values and recognizes receiving the alarm cell.

Since the bit with bit value 1 exists between the first and second bits in the VCI field, the network-connection node 110 decides that the path between the ring node 3 (130) and the ring node 4 (140) has been interrupted.

As such, the network-connection node 110 cut off of the port of no ATM cell is received from the ring nodes 4 and 5 (140 and 150) through the fault path, and interlinks a port for receiving ATM cells from the ring nodes 4 and 5 (140 and 150) through a normal path only.

Even though the above discussion illustrated the alarm cell that is generated by the ring node 3 (130), the ring node 4 (140) can also generate and transmit an alarm cell toward the network-connection node 110 in like manner, and upon receiving the alarm cell, the ring node 5 (150) and network-connection node 110 perform a switching process.

More specifically, the ring node 120-150 performs the switching process in a direction of receiving ATM cells from the network-connection node 110, but the network-connection node 110 performs the switching process on the entire ring nodes 120-150.

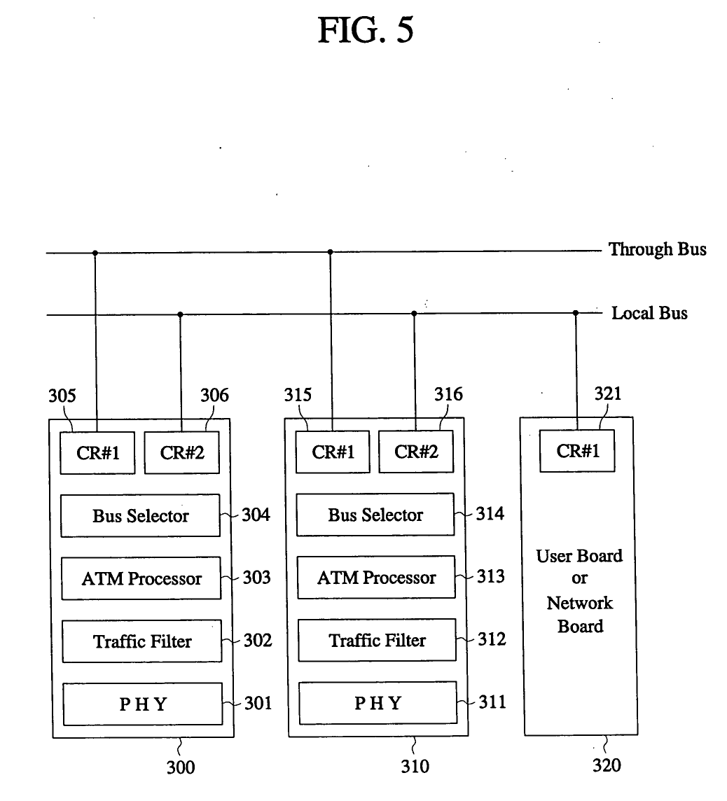

FIG. 5 diagrammatically illustrates the internal structure of a protection switching apparatus using a node group in the ring ATM system according to one embodiment of the present invention.

Referring to FIG. 5, the protection switching apparatus using a node group in the ring ATM system includes NAUs (Network ATM ring Unit), which is a board for use in constructing a ring in each direction (counterclockwise and clockwise). In case of the network-connection node, the apparatus further includes a network board for connecting to an external network and in case of the ring node, the apparatus includes a user board 320.

Each NAU 300, 310 has a physical layer processor (PHY) 301, 311, a traffic filter 302, 312, an ATM processor 303, 313, a bus selector 304, 314, a cell router #1 305, 315, and a cell router #2 306, 316. In addition, the apparatus includes a through bus for passing through subscriber traffic in another ring node of the ring, and a local bus for adding/dropping the subscriber traffic in a corresponding node.

Also, the network board or user board 320 has a cell router #1 321.

The physical layer processor 301, 311 receives a frame from the physical layer, extracts an ATM cell therefrom, and transmits the ATM cell to the traffic filter 302, 312.

The traffic filter 302, 312 has a cell drop register, and the cell drop register for storing RNID of a cell to be dropped.

On receiving the cell from the physical layer processor 301, 311, the traffic filter 302, 312 extracts a GFC field value of the receive cell, and checks if the extracted GFC field value is included in the cell drop register. If the extracted GFC field value is found in the cell drop register, the traffic filter drops the cell, but if not, transmits the cell to the ATM processor 303, 313.

On receiving the cell from the traffic filter 302, 312, the ATM processor 303, 313 sets a specific bit of the routing field to 1 if the GFC field value is identical with its own RNID. However, if the GFC field value is not the same with its RNID, the ATM processor 303, 313 sets the specific bit of the routing field to 0 and transmits the cell to the bus selector 304, 314.

If the specific bit of the input ATM cell from the ATM processor 303, 313 is 0, the bus selector 304, 314 transmits the cell to the cell router #1 305, 315, and if the specific bit is 1, transmits the cell to the cell router #2 306, 316.

Then the cell router #1 305, 315 transmits the cell from the bus selector 304, 314 to the through bus, while the cell router #2 306, 316 transmits the cell from the bus selector 304, 314 to the local bus.

The cell being transmitted to the local bus is sent out to the ATM network through the network board or user board 320, or to a user's subscriber line.

The cell being transmitted to the through bus is sent out to the ring network through the NAU 300, 310 in the opposite direction.

At this time, the input cell from the user's subscriber line or from the external ATM network is loaded onto the local bus through the network board or user board 320, and transmitted in first/second direction through each of the NAUs 300 and 310.

In the meantime, when the traffic filter 302, 312 receives an alarm cell, it recognizes it as the alarm cell given that the GFC field value is 1xF and the VPI field value is 0xFF.

In case the traffic filter 302, 312 is located at the ring node NAU 300, 310, a controller for controlling the entire NAU 300, 310 is informed about receiving the alarm cell.

Then the controller performs the switching process by storing its RNID in the cell drop register of the alarm cell-receiving NAU 300, 310, and deleting its RNID having been stored in the cell drop register of the NAU 300, 310 of the opposite direction.

Also the controller sets its allocated VCI bit to 1, and controls the NAU to transmit the cell through the through bus.

Similarly, in case the traffic filter 302, 312 is located at the network-connection node NAU 300, 310, the controller for controlling the entire NAU 300, 310 is informed about receiving the alarm cell. To perform the switching process, the controller extracts the VCI bit value, and deletes the RNID of the ring node with the bit value 1 from the cell drop register of the alarm cell-receiving NAU 300, 310, and stores the RNID of the ring node in the cell drop register of the NAU 300, 310 of the opposite direction.

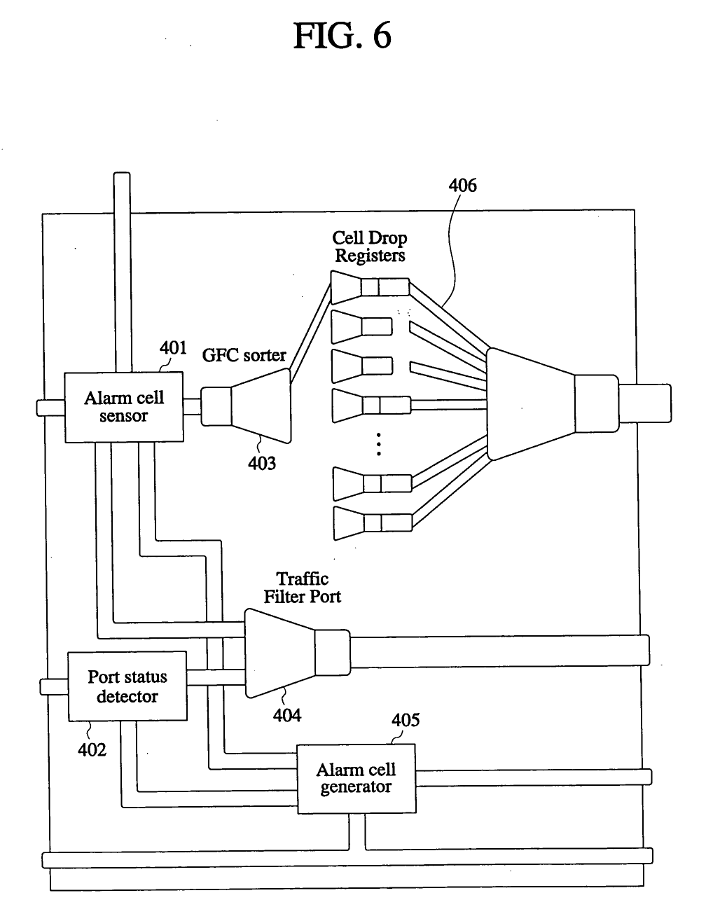

FIG. 6 is a conceptual diagram of the internal structure of a traffic filter illustrated in FIG. 5.

Referring to FIG. 6, the traffic filter (302, 312) has an alarm cell sensor 401, a port status detector 402, a GFC sorter 403, a traffic filter porter 404, an alarm cell generator 405, and a cell drop register 406.

The alarm cell sensor 401 senses an alarm cell among input ATM cells from the PHY (301, 311), and compares the present input value to a previously input alarm cell.

At the result of the comparison, if it turns out that the two values are different from each other, the alarm cell sensor 401 stores the new input value and generates an interrupt and notifies this to the controller that controls the NAU.

The port status detector 402 detects the status of a port. If the port is failed or interrupted, the port status detector 402 notifies such to the alarm cell generator of the NAU in a pair through the traffic filter port 404.

The GFC sorter 403 checks the GFC field of the receive ATM cell and transmits a corresponding cell to the GFC field value to the cell drop register 406.

The traffic filter port 404 is a channel for exchanging the information about the reception status of the present alarm cell and status of port between the NAU in a pair.

The alarm cell generator 405 periodically generates an alarm cell using the information about the alarm cell and status of port from the NAU in a pair, and transmits the alarm cell through the PHY.

The cell drop register 406 decides whether or not to pass an input cell, and there are a total of 16 registers. If a port exists through an ATM process, the cell drop register 406 passes the receive cell, but if not, the cell drop register 406 drops the cell.

The following describes an operation of the traffic filter, referring to FIG. 6.

Referring to FIG. 6, the alarm cell sensor 401 senses an alarm cell among receive ATM cells from the PHY (301, 311), and compares the present receive value to a previously input alarm cell.

At the result of comparison, if it turns out that the two values are different from each other, the alarm cell sensor 401 stores the new receive value and generates an interrupt and notifies this to the controller that controls the NAU.

If the GFC field value is 1xF and the VPI field value is 0xFF, the alarm cell sensor 401 recognizes the receive cell as an alarm cell, and transmits RNID information of a node with a bit value 1 in the VCI field to the controller.

Then the controller stores its RNID in the cell drop register of the NAU that received the alarm information, and deletes its RNID from the cell drop register of the NAU in pair. In this manner, the switching process is performed.

On the other hand, the alarm cell sensor 401, if what it sensed is not an alarm cell, transmits the cell to the GFC sorter 403 in which the cell is processed normally.

The GFC sorter 403 checks the GFC field of the receive ATM cell and transmits the cell to the cell drop register 406 corresponding to the GFC field value.

The cell drop register 406 decides whether or not to pass a receive cell, and there are a total of 16 registers. If a port exists through an ATM process, the cell drop register 406 passes the receive cell, but if not, the cell drop register 406 drops the cell.

Also, the port status detector 402 detects the status of a port whether the port has a fault in it and informs the port fault to the alarm cell generator 405.

Then the alarm cell generator 405 in pair of the NAU generates an alarm cell by designating 1xF to the GFC field and 0xFF to the VPI field, and setting its allocated bit value in the VCI 1 field to be 1, and transmits the alarm cell.

Meanwhile, if the alarm cell generator 405 receives an alarm cell having been generated from the alarm cell generator of another ring node, it sets its allocated bit value in the VCI field of the received alarm cell to generate an alarm cell, and transmits this generated alarm cell.

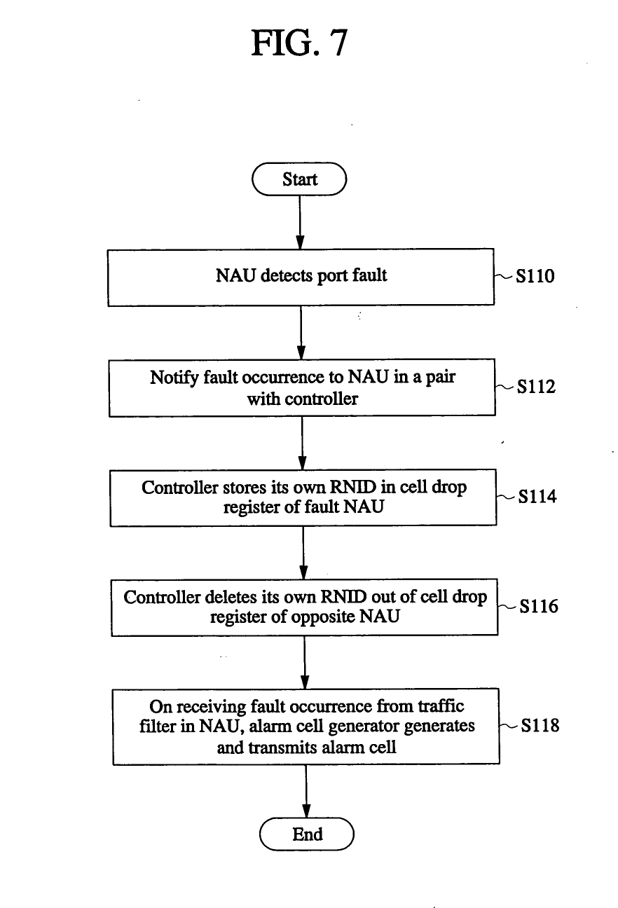

FIG. 7 is a flow chart describing a protection switching method in a ring node fault according to one embodiment of the present invention.

Referring to FIG. 7, the protection switching method in a ring node fault according to one embodiment of the present invention starts with detecting a port fault in the NAU of the ring node (S110). NAU informs the result of port detect to a NAU paired with the controller for controlling the NAU (S112).

Later, the controller stores its RNID in the cell drop register of the fault NAU's traffic filter for the drop cell that has the GFC field value as its RNID value (S114).

Next, the controller deletes its RNID from the cell drop register of the opposite NAU to which the fault occurrence has been notified, whereby the GFC field allows its RNID cell to pass through the traffic filter (S116).

The alarm cell generator of the traffic filter in the NAU to which the fault occurrence has been notified generates an alarm cell by designating 1xF as the field value for the GFC field and 0xFF for the VCI field and setting its allocated bit in the VCI field to 1. Then the alarm cell generator periodically transmits the generated alarm cell clockwise (S118).

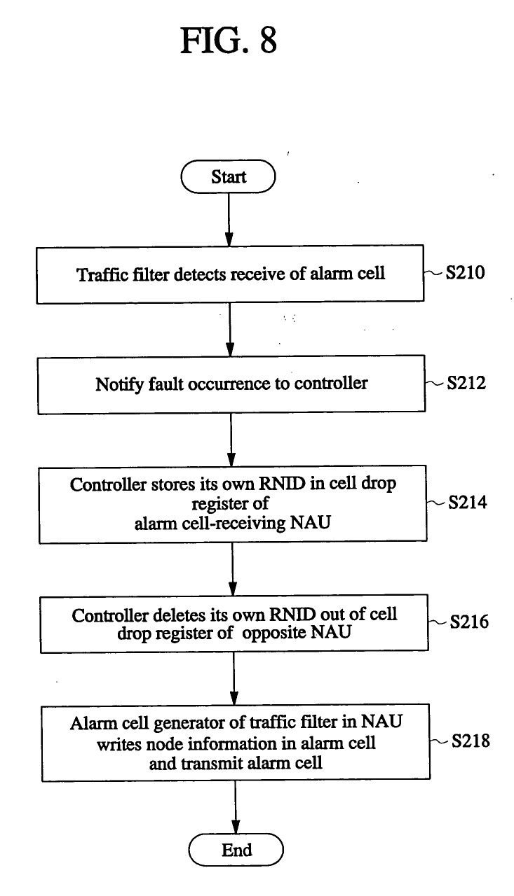

FIG. 8 is a flow chart describing a protecting switching method in a ring node to which an alarm cell is transmitted according to one embodiment of the present invention.

Referring to FIG. 8, the protecting switching method in a ring node to which an alarm cell is received, the NAU's traffic filter extracts the GFC field and VPI field values of an receive cell, and recognizes the receive cell as an alarm cell if the extracted GFC field value is 1xF and the VPI field value is 0xFF (S210), and notifies the fault occurrence to the controller of the NAU (S212).

The controller stores its RNID in the cell drop register of the NAU's traffic filter that, the alarm cell receiving for drop a cell, has the GFC field value as its RNID value (S214).

In addition, the controller deletes its RNID from the cell drop register of the traffic filter of the opposite NAU to the alarm cell-receiving NAU, and interlinks a port for passing the alarm cell provided that the GFC filed value is identical with its RNID (S216).

Next, the alarm cell generator in the alarm cell-receiving NAU adds its node information to the received alarm cell and periodically transmits the alarm cell including its node information (S218).

The step for adding node information of the alarm cell generator is done by setting its allocated bit value in the VCI field of the alarm cell to 1.

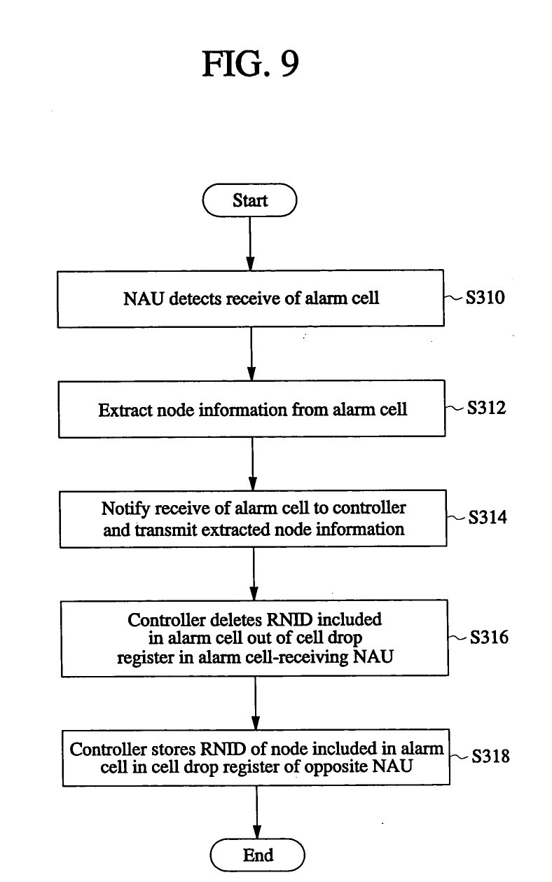

FIG. 9 is a flow chart describing a protection switching method in a network-connection node when an alarm cell is transmitted thereto.

Referring to FIG. 9, when the network-connection node receives an alarm cell, the NAU detects that the alarm cell has been received (S310), and extracts node information of what bit is value 1 in the VCI field of the receiving alarm cell (S312).

Next, the traffic filter of the NAU that has detected the receive of the alarm cell, notifies the received alarm cell to the controller of the NAU and transmits the node information extracted from the alarm cell (S314).

Later the controller deletes RNIDs of nodes from the cell drop register of the alarm cell-receiving NAU's traffic filter, on the basis of node information included in the alarm cell, and includes the deleted RNIDs in the GFC field instead to allow the receive cells to pass (S316).

Moreover, the controller stores the RNIDs of nodes based on the node information included in the alarm cell in the cell drop register of the traffic filter in the opposite NAU to the alarm cell-receiving NAU, and the cell that has the stored RNIDs included in the GFC field to drop receive cells (S318).

The present invention can be realized as computer-executable instructions in computer-readable media. The computer-readable media includes all possible kinds of media in which computer-readable data is stored or included or can include any type of data that can be read by a computer or a processing unit. The computer-readable media include for example and not limited to storing media, such as magnetic storing media (e.g., ROMs, floppy disks, hard disk, and the like), optical reading media (e.g., CD-ROMs (compact disc-read-only memory), DVDs (digital versatile discs), re-writable versions of the optical discs, and the like), hybrid magnetic optical disks, organic disks, system memory (read-only memory, random access memory), non-volatile memory such as flash memory or any other volatile or non-volatile memory, other semiconductor media, electronic media, electromagnetic media, infrared, and other communication media such as carrier waves (e.g., transmission via the Internet or another computer). Communication media generally embodies computer-readable instructions, data structures, program modules or other data in a modulated signal such as the carrier waves or other transportable mechanism including any information delivery media. Computer-readable media such as communication media may include wireless media such as radio frequency, infrared microwaves, and wired media such as a wired network. Also, the computer-readable media can store and execute computer-readable codes that are distributed in computers connected via a network. The computer readable medium also includes cooperating or interconnected computer readable media that are in the processing system or are distributed among multiple processing systems that may be local or remote to the processing system. The present invention can include the computer-readable medium having stored thereon a data structure including a plurality of fields containing data representing the techniques of the present invention.

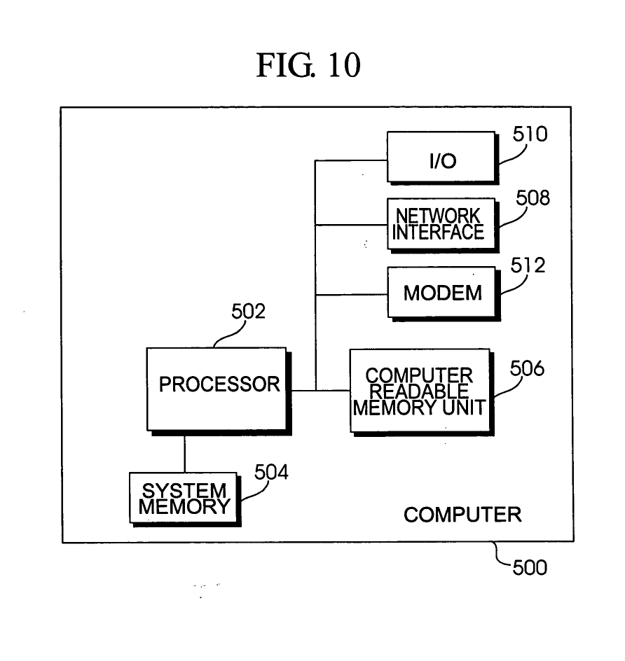

An example of a computer, but not limited to this example of the computer, that can read computer readable media that includes computer-executable instructions of the present invention is shown in FIG. 10. The computer 500 includes a processor 502 that controls the computer 500. The processor 502 uses the system memory 504 and a computer readable memory device 506 that includes certain computer readable recording media. A system bus connects the processor 502 to a network interface 508, modem 512 or other interface that accommodates a connection to another computer or network such as the Internet. The system bus may also include an input and output interface 510 that accommodates connection to a variety of other devices.

In conclusion, the protection switching process can be completed much faster than in the related art by using the GFC field for the ring ATM system.

While the invention has been described in conjunction with various embodiments, they are illustrative only. Accordingly, many alternative, modifications and variations will be apparent to persons skilled in the art in light of the foregoing detailed description. The foregoing description is intended to embrace all such alternatives and variations falling with the spirit and broad scope of the appended claims.

What is claimed is:

1. A protection switching apparatus using a node group in a ring asynchronous transfer mode system, the apparatus comprising:
a physical layer processor extracting an asynchronous transfer mode cell from a receive frame from a physical layer and loading a cell that is received from an asynchronous transfer mode layer to the frame;
a pair of traffic filters for generating an alarm cell when fault is sensed in the opposite port, for transmitting the alarm cell, each of the traffic filters comprising a cell drop register for storing ring node identification, with when a cell with a designated ring node identification from a unidirectional network interface is received in a first field that is stored in a cell drop register, the traffic filter drops the cell, and when a cell with a designated ring node identification is inputted in a first field that is not stored in the cell drop register, the traffic filter passes the cell, for detecting an alarm cell that is received from another ring node, for setting an allocated bit value in a second field to a second value, and for transmitting the cell;
a controller for storing a ring node identification of its own in the cell drop register of the traffic filter that transmitted the alarm cell recognition signal when receiving an alarm cell recognition signal from the traffic filter, for deleting the ring node identification, and for transmitting a control signal to set its allocated bit in the alarm cell to the traffic filter; and
a cell routing unit for routing the cell to a local bus when receiving a cell with its designated ring node identification to the first field of the receive cell, and for routing the cell to a through bus when receiving a cell without its designated ring node identification to the first field of the receive cell.

2. The apparatus according to claim 1, wherein the alarm cell comprises:
a generic flow control field to which 1xF is allocated as a third value;
a virtual channel identifier field to which 0xFF is allocated as a fourth value; and
a virtual path identifier field including a bit that is set to 1 having allocated 1 as the second value.

3. The apparatus according to claim 1, wherein the traffic filter comprises:
a cell drop register for storing ring node identification, informing a cell to drop;
a traffic filter port for providing a port to exchange information about reception status of the alarm cell and port status between the traffic filters in a pair;
an alarm cell generator for generating and transmitting an alarm cell when a port fault indication signal is received, for receiving a cell from another ring node and transmitting the cell, for detecting an alarm cell in the cell from another ring node, and for allocating its allocated bit in the second field as the second value;
a port status detector for detecting status of a port, and when port fault is sensed, for outputting the port fault indication signal to the traffic filter paired with the controller; and
a generic flow control sorter for dropping the cell when the first field value of the receive cell from the alarm cell generator exists in the cell drop register, and for passing the cell when the first field value of the input cell from the alarm cell generator does exist in the cell drop register.

4. The apparatus according to claim 1, wherein the cell routing unit comprises:
a first cell router for routing the cell to the through bus that passes a subscriber traffic in another ring node within the ring;
a second cell router for routing the cell to the local bus that adds or drops the subscriber traffic in a corresponding node;
a bus selector for routing the cell to the first cell router when a fourth value is designated to a fourth field of the receive cell, and for routing the cell to the second cell router when the fourth value is not designated to the fourth field; and
an asynchronous transfer mode processor for setting the fourth value to the fourth field when receiving the cell with its designated ring node identification to the first field from the traffic field, and for transmitting the cell to the bus selector.

5. A protection switching method using a node group in a ring asynchronous transfer mode system, the method comprising:
recognizing, by a network asynchronous transfer mode ring unit of a ring node, port fault and notifying to an opposite network asynchronous transfer mode ring unit about the port fault;
designating, by a controller, a ring node identification of the controller to a cell drop register of the network asynchronous transfer mode ring unit with the port fault, and deleting the ring node identification out of a cell drop register of the opposite network asynchronous transfer mode ring unit;
generating an alarm cell and transmitting the alarm cell by the network asynchronous transfer mode ring unit that is notified of the port fault;
upon receiving an alarm cell from another ring node, designating a ring node identification of the controller to the cell drop register of an alarm cell-receiving network asynchronous transfer mode ring unit by the controller and deleting the ring node identification out of the cell drop register of the opposite network asynchronous transfer mode ring unit by the controller; and
writing node information of the unit to the input alarm cell and transmitting the alarm cell including the node information of the unit by the alarm cell-receiving network asynchronous transfer mode ring unit.

6. The method according to claim 5, wherein the alarm cell at the step of generating an alarm cell and transmitting the alarm cell, comprises 1xF as a field value for a generic flow control field, 0xFF as a field value for a virtual path identifier field, and an allocated bit to the alarm cell in a virtual channel identifier field is 1.

7. The method according to claim 5, wherein the step of designating the ring node identification and deleting the ring node identification comprises the sub-steps of:
extracting, at a traffic filter of the network asynchronous transfer mode ring unit, a generic flow control field value and a virtual path identifier field value of the receive cell, and when the generic flow control field value is 1xF and the virtual path identifier field value is 0xFF, recognizing the receive cell as an alarm cell, and notifying fault occurrence to the controller;
storing, at the controller, the ring node identification of the controller in the cell drop register of the traffic filter of the alarm cell-receiving network asynchronous transfer mode ring unit; and
deleting, at the controller, the ring node identification of the controller out of the cell drop register of the opposite network asynchronous transfer mode ring unit to the alarm cell-receiving network asynchronous transfer mode ring unit.

8. A protection switching method using a node group in a ring asynchronous transfer mode system, the method comprising the steps of:
when a network-connection node receives an alarm cell, detecting, at a network asynchronous transfer mode ring unit, that the alarm cell has been received, and extracting node information from the alarm cell;
notifying, at the network asynchronous transfer mode ring unit that detected receive of the alarm cell, to a controller about the receive of the alarm cell, and transmitting the node information extracted from the alarm cell to the controller;
deleting, at the controller, ring node identifications of nodes based on the node information included in the alarm cell of a cell drop register of the network asynchronous transfer mode ring unit in which the alarm cell is received; and
storing, at the controller, ring node identifications of nodes based on the node information included in the alarm cell of an cell drop register of an opposite network asynchronous transfer mode ring unit of the network asynchronous transfer mode ring unit to which the alarm cell is inputted.

9. A computer-readable medium having computer-executable instructions for performing a method, comprising:
recognizing, by a network asynchronous transfer mode ring unit of a ring node, port fault and notifying to an opposite network asynchronous transfer mode ring unit about the port fault;
designating, by a controller, a ring node identification of the controller to a cell drop register of the network asynchronous transfer mode ring unit with the port fault, and deleting the ring node identification out of a cell drop register of the opposite network asynchronous transfer mode ring unit;
generating an alarm cell and transmitting the alarm cell by the network asynchronous transfer mode ring unit that is notified of the port fault;
upon receiving an alarm cell from another ring node, designating a ring node identification of the controller to the cell drop register of an alarm cell-receiving network asynchronous transfer mode ring unit by the controller and deleting the ring node identification out of the cell drop register of the opposite network asynchronous transfer mode ring unit by the controller; and
writing node information of the unit to the input alarm cell and transmitting the alarm cell including the node information of the unit by the alarm cell-receiving network asynchronous transfer mode ring unit.

10. The computer-readable medium having computer-executable instructions for performing the method of claim 9, wherein the alarm cell at the step of generating an alarm cell and transmitting the alarm cell, comprises a first value as a field value for a generic flow control field, second value as a field value for a virtual path identifier field, and an allocated bit to the alarm cell in a virtual channel identifier field is 1, the first value being a value different than the allocated ring node identifications, the second value being value different than the allocated ring node identifications and different than the first value.

11. The computer-readable medium having computer-executable instructions for performing the method of claim 10, with the designating of the ring node identification and deleting the ring node identification comprises:
extracting, at a traffic filter of the network asynchronous transfer mode ring unit, a generic flow control field value and a virtual path identifier field value of the receive cell, and when the generic flow control field value is the first value and the virtual path identifier field value is the second value, recognizing the receive cell as an alarm cell, and notifying fault occurrence to the controller;
storing, at the controller, the ring node identification of the controller in the cell drop register of the traffic filter of the alarm cell-receiving network asynchronous transfer mode ring unit; and
deleting, at the controller, the ring node identification of the controller out of the cell drop register of the opposite network asynchronous transfer mode ring unit to the alarm cell-receiving network asynchronous transfer mode ring unit.

12. A computer-readable medium having stored thereon a data structure comprising:
a first field containing data representing, when a network-connection node receives an alarm cell, detecting, at a network asynchronous transfer mode ring unit, that the alarm cell has been received, and extracting node information from the alarm cell;
a second field containing data representing notifying, at the network asynchronous transfer mode ring unit that detected receive of the alarm cell, to a controller about the receive of the alarm cell, and transmitting the node information extracted from the alarm cell to the controller;
a third field containing data representing deleting, at the controller, ring node identifications of nodes based on the node information included in the alarm cell of a cell drop register of the network asynchronous transfer mode ring unit in which the alarm cell is received; and
fourth field containing data representing storing, at the controller, ring node identifications of nodes based on the node information included in the alarm cell of an cell drop register of an opposite network asynchronous transfer mode ring unit of the network asynchronous transfer mode ring unit to which the alarm cell is inputted.
